(19) United States
(12) Patent Application Publication
(10) Pub. No.: US 2005/0101108 A1
(43) Pub. Date: May 12, 2005

(54) Semiconductor wafer dividing method

(76) Inventors: Satoshi Genda, Tokyo (JP); Masaru Nakamura, Tokyo (JP)

Correspondence Address: SMITH, GAMBRELL & RUSSELL, LLP, 1850 M STREET, N.W., SUITE 800, WASHINGTON, DC, 20036, US

(21) Appl. No.: 10/981,523

(22) Filed: Nov. 5, 2004

(30) Foreign Application Priority Data
Nov. 7, 2003 (JP) 2003-378057

(51) Int. Cl. H01L 21/301; H01L 21/46; H01L 21/78

(52) U.S. Cl. 438/462

(57) ABSTRACT

A method of dividing a semiconductor wafer comprising semiconductor chips which are composed of a laminate consisting of an insulating film and a functional film formed on the front surface of a semiconductor substrate and which are sectioned by streets, into individual semiconductor chips by cutting the semiconductor wafer with a cutting blade along the streets, the method comprising a first groove forming step for forming a pair of first laser grooves in the laminate by applying a first laser beam to each of the streets at a distance wider than the width of the cutting blade; a second groove forming step for forming second laser grooves which reach the semiconductor substrate between the both outer sides of the pair of first laser grooves in the street by applying a second laser beam to the laminate of a region wider than the width of the cutting blade; and a cutting step for cutting the semiconductor substrate with the cutting blade along the second laser grooves.

### FIELD OF THE INVENTION

The present invention relates to a method of dividing a semiconductor wafer along streets, the semiconductor wafer comprising semiconductor chips which are composed of a laminate consisting of an insulating film and a functional film formed on the surface of a semiconductor substrate such as a silicon substrate or the like and which are sectioned by the streets.

### DESCRIPTION OF THE PRIOR ART

As is known to people of ordinary skill in the art, a semiconductor wafer comprising a plurality of semiconductor chips such as IC's or LSI's, composed of a laminate consisting of an insulating film and a functional film, which are formed in a matrix on the front surface of a semiconductor substrate such as a silicon substrate, is formed in the production process of a semiconductor device. In the semiconductor wafer thus formed, the above semiconductor chips are sectioned by dividing lines called “streets”, and individual semiconductor chips are produced by cutting the semiconductor wafer along the streets. Cutting along the streets of the semiconductor wafer is generally carried out by a cutting machine called “dicer”. This cutting machine comprises a chuck table for holding a semiconductor wafer as a workpiece, a cutting means for cutting the semiconductor wafer held on the chuck table, and a moving means for moving the chuck table and the cutting means relative to each other. The cutting means comprises a rotary spindle which is turned at a high speed and a cutting blade mounted to the spindle. The cutting blade comprises a disk-like base and an annular cutting edge that is mounted on the side wall peripheral portion of the base and formed as thick as about 20 μm by fixing diamond abrasive grains having a diameter of about 3 μm to the base by electroforming.

To improve the throughput of a semiconductor chip such as IC or LSI, a semiconductor wafer comprising semiconductor chips which are composed of a laminate consisting of a low-dielectric insulating film (Low-k film) formed of a film of an inorganic material such as SiOF or BSG (SiOB) or a film of an organic material such as a polyimide-based or parylene-based polymer and a functional film forming circuits on the front surface of a semiconductor substrate such as a silicon substrate has recently been implemented.

When the above semiconductor wafer having a Low-k film laminated thereon is cut along the streets with a cutting blade, a problem occurs in that the Low-k film peels off and this peeling reaches the circuits and causes a fatal damage to a semiconductor chip, as the Low-k film is extremely fragile like mica. Even in a semiconductor wafer having no Low-k film, when the film laminated on the front surface of the semiconductor substrate is cut along the streets with a cutting blade, a problem occurs that it peels off due to destructive power generated by the cutting operation of the cutting blade, thereby damaging the semiconductor chips.

To solve the above problems, a dividing method for applying a laser beam along the streets of a semiconductor wafer to remove a laminate comprising a Low-k film that forms the streets and then, positioning a cutting blade to the area from which the laminate has been removed to cut the semiconductor wafer is attempted. A processing machine for carrying out the above dividing method is disclosed in JP-A 2003-320466.

In the above dividing method, the laminate comprising the Low-k film that forms the streets is removed by applying a laser beam. However, a problem occurs that if a laser beam having high output capable of removing the laminate comprising the Low-k film is applied at one time, a film forming the laminate peels off by the destructive power of the laser beam with the consequence that semiconductor chips such as IC's or LSI's may be damaged.

### SUMMARY OF THE INVENTION

It is an object of the present invention to provide a semiconductor wafer dividing method that allows to divide a semiconductor wafer comprising semiconductor chips which are composed of a laminate consisting of an insulating film and a functional film formed on the front surface of a semiconductor substrate and are sectioned by streets, into individual semiconductor chips along the streets without peeling off the laminate.

According to the present invention, the above object is attained by a method of dividing a semiconductor wafer comprising semiconductor chips which are composed of a laminate consisting of an insulating film and a functional film formed on the front surface of a semiconductor substrate and which are sectioned by streets, into individual semiconductor chips by cutting the semiconductor wafer with a cutting blade along the streets, the method comprising:
a first groove forming step for forming a pair of first laser grooves in the laminate by applying a first laser beam to each of the streets at a distance wider than the width of the cutting blade;
a second groove forming step for forming second laser grooves which reach the semiconductor substrate between the both outer sides of the pair of first laser grooves in the street by applying a second laser beam to the laminate of a region wider than the width of the cutting blade; and
a cutting step for cutting the semiconductor substrate with the cutting blade along the second laser grooves.

The output of the first laser beam is set to be lower than the output of the second laser beam. The depth of the first laser grooves is set to the depth of an easily peelable film layer when the second laser beam is applied in the second groove forming step.

According to the present invention, after a pair of first laser grooves are formed in the laminate by applying a first laser beam to each of the streets at a distance wider than the width of the cutting blade, second laser grooves which reach the semiconductor substrate are formed between the both outer sides of the pair of first laser grooves by applying a second laser beam to the laminate of a region wider than the width of the cutting blade. Therefore, even when the laminate is peeled off by applying the second laser beam, as the semiconductor chips are divided off at both sides by the first laser grooves, they are not affected by the peeling. Since the laminate is completely separated from the chips by the second laser grooves in the step of cutting along the second laser grooves with the cutting blade, the semiconductor chips are not affected by the peeling of the laminate.

### BRIEF DESCRIPTION OF THE DRAWINGS

FIG. 1 is a perspective view of a semiconductor wafer to be divided by the present invention, which is mounted on a frame by a protective tape;

FIG. 2 is an enlarged sectional view of the semiconductor wafer shown in FIG. 1;

FIG. 3 is a perspective view of the principal portion of a laser beam machine for carrying out the first groove forming step and the second groove forming step in the semiconductor wafer dividing method of the present invention;

FIG. 4 is a schematic block diagram showing the constitution of laser beam application means provided in the laser beam machine shown in FIG. 3;

FIG. 5 is a schematic diagram for explaining the focusing spot diameter of a laser beam;

FIGS. 6(a) and 6(b) are diagrams for explaining the first groove forming step in the semiconductor wafer dividing method of the present invention;

FIG. 7 is a diagram showing first laser beam application positions in the first groove forming step in the semiconductor wafer dividing method of the present invention;

FIG. 8 is a diagram showing first laser grooves formed in the semiconductor wafer by the first groove forming step in the semiconductor wafer dividing method of the present invention;

FIG. 9 is a diagram showing second laser beam application positions in the second groove forming step in the semiconductor wafer dividing method of the present invention;

FIG. 10 is a diagram showing second laser grooves formed in the semiconductor wafer by the second groove forming step in the semiconductor wafer dividing method of the present invention;

FIG. 11 is a diagram showing another embodiment of the second laser grooves formed in the semiconductor wafer by the second groove forming step in the semiconductor wafer dividing method of the present invention;

FIG. 12 is a perspective view of the principal portion of a cutting machine for carrying out the cutting step in the semiconductor wafer dividing method of the present invention;

FIGS. 13(a) and 13(b) are diagrams for explaining the cutting step in the semiconductor wafer dividing method of the present invention; and

FIGS. 14(a) and 14(b) are diagrams showing a state where the semiconductor wafer is cut along the second laser grooves by the cutting step in the semiconductor wafer dividing method of the present invention.

### DETAILED DESCRIPTION OF THE PREFERRED EMBODIMENTS

A semiconductor wafer dividing method according to preferred embodiments of the present invention will be described in detail hereinunder with reference to the accompanying drawings.

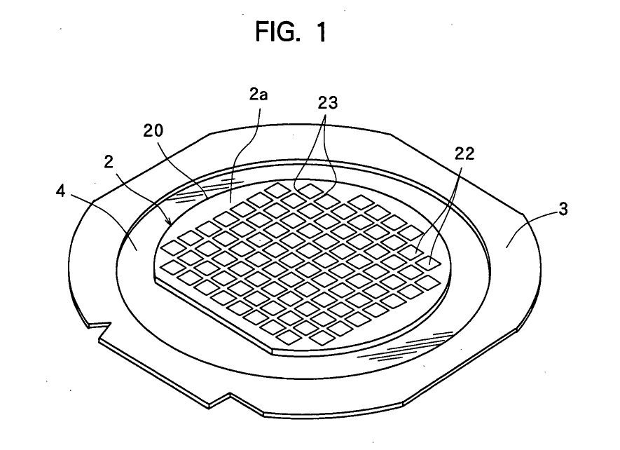

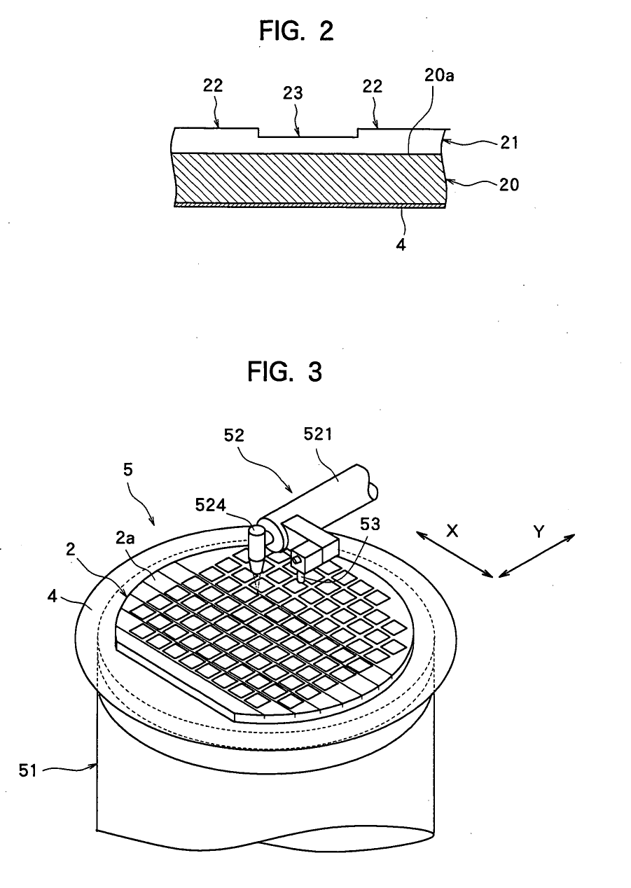

FIG. 1 is a perspective view of a semiconductor wafer to be divided according to the present invention, and FIG. 2 is an enlarged sectional view of the principal portion of the semiconductor wafer shown in FIG. 1. In the semiconductor wafer 2 shown in FIG. 1 and FIG. 2, a plurality of semiconductor chips 22 such as IC's or LSI's composed of a laminate 21 consisting of an insulating film and a functional film forming circuits are formed in a matrix on the front surface 20a of a semiconductor substrate 20 such as a silicon substrate, as shown in FIG. 2. The semiconductor chips 22 are sectioned by streets 23 formed in a lattice pattern. In the illustrated embodiment, the insulating film forming the laminate 21 is a low-dielectric insulating film (Low-k film) 23 formed of a film of an inorganic material such as SiOF or BSG (SiOB) or a film of an organic material such as polyimide-based or parylene-based polymers. The back surface of the semiconductor wafer 2 thus formed is put to a protective tape 4 affixed to an annular frame 3 as shown in FIG. 1 so that when it is divided into individual semiconductor chips, the semiconductor chips 22 do not fall apart.

In the method of dividing the semiconductor wafer 2 according to the present invention, a first groove forming step for forming a pair of first laser grooves in the laminate 21 by applying a first laser beam along the street 23 formed on the semiconductor wafer 2 at a distance wider than the width of a cutting blade which will be described later is first carried out. This first groove forming step is carried out by using a laser beam machine shown in FIGS. 3 to 5. The laser beam machine 5 shown in FIGS. 3 to 5 has a chuck table 51 for holding a workpiece, a laser beam application means 52 for applying a laser beam to the workpiece held on the chuck table 51 and an image pick-up means 53 for picking up an image of the workpiece held on the chuck table 51. The chuck table 51 is so constituted to suction-hold the workpiece, and is moved by a moving mechanism (not shown) in a processing-feed direction indicated by an arrow X and an indexing-feed direction indicated by an arrow Y in FIG. 3.

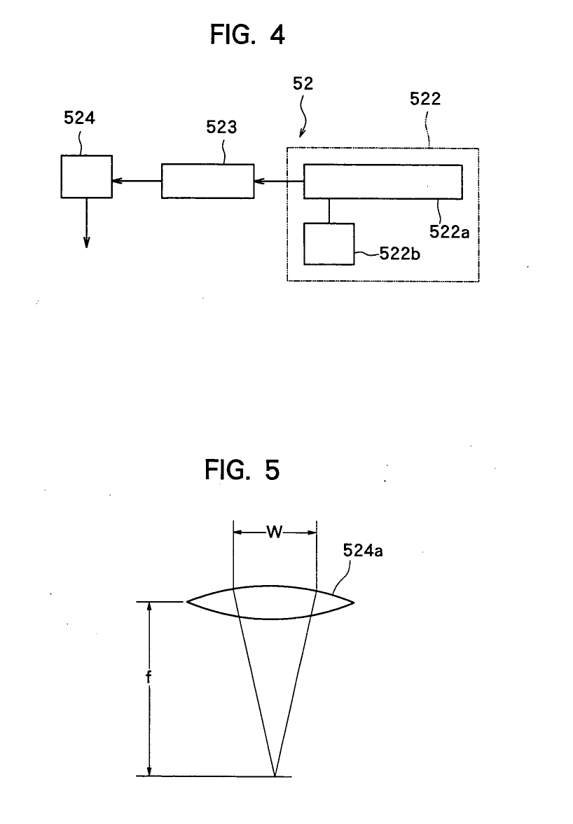

The above laser beam application means 52 has a cylindrical casing 521 arranged substantially horizontally. In the casing 521, there are installed a pulse laser beam oscillation means 522 and a transmission optical system 523 as shown in FIG. 4. The pulse laser beam oscillation means 522 is constituted by a pulse laser beam oscillator 522a composed of a YAG laser oscillator or YVO4 laser oscillator and a repetition frequency setting means 522b connected to the pulse laser beam oscillator 522a. The transmission optical system 523 comprises suitable optical elements such as a beam splitter, etc. A condenser 524 housing condensing lenses (not shown) constituted by a set of lenses that may be a known formation is attached to the end of the above casing 521. A laser beam oscillated from the above pulse laser beam oscillation means 522 reaches the condenser 524 through the transmission optical system 523 and is applied from the condenser 524 to the workpiece held on the above chuck table 51 at a predetermined focusing spot diameter D. The focusing spot diameter D is defined by the expression D (μm)=4×λ×f/(π×W) (wherein λ is the wavelength (μm) of the pulse laser beam, W is the diameter (mm) of the pulse laser beam applied to an objective condenser lens 524a, and f is the focusing distance (mm) of the objective condenser lens 524a) when the pulse laser beam having a Gauss distribution is applied through the objective condenser lens 524a of the condenser 524 as shown in FIG. 5.

The image pick-up means 53 mounted on the end of the casing 521 constituting the above laser beam application means 52 is constituted by an ordinary image pick-up device (CCD) for picking up an image with visible radiation in the illustrated embodiment. An image signal is transmitted to a control means that will be described later.

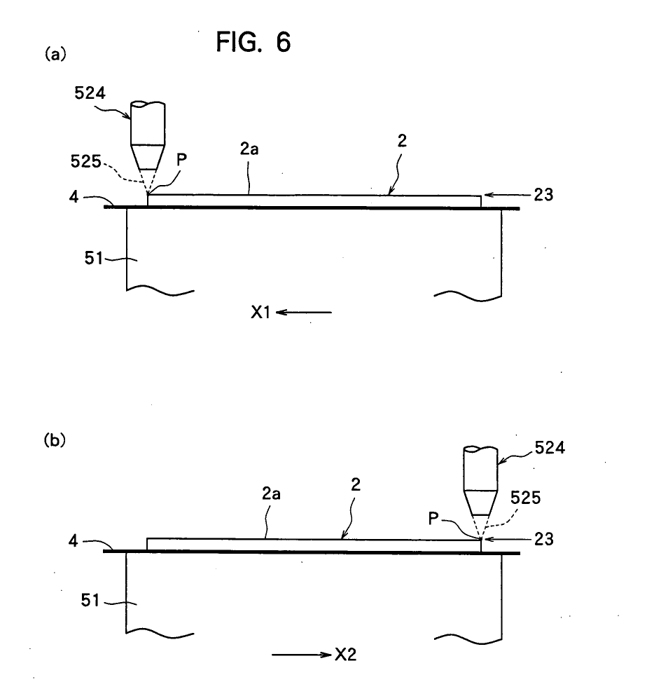

The first groove forming step which is carried out by using the above laser beam machine 5 will be described with reference to FIG. 3, FIGS. 6(a) and 6(b), and FIG. 7.

In the first groove forming step, the semiconductor wafer 2 is first placed on the chuck table 51 of the laser beam machine 5 shown in FIG. 3 in such a manner that the front surface 2a (on the side where the laminate 21 is formed) faces up and suction-held on the chuck table 51. In FIG. 3, the annular frame 3 having the protective tape 4 affixed thereto is omitted. The annular frame 3 is held by a suitable frame holding means provided to the chuck table 51.

The chuck table 51 suction-holding the semiconductor wafer 2 as described above is positioned right below the image pick-up means 53 by a moving mechanism that is not shown. After the chuck table 51 is positioned right below the image pick-up means 53, alignment work for detecting the processing area to be processed of the semiconductor wafer 2 is carried out by the image pick-up means 53 and a control means that is not shown. That is, the image pick-up means 53 and the control means (not shown) carry out image processing such as pattern matching and so on to align a street 23 formed in a predetermined direction of the semiconductor wafer 2 with the condenser 524 of the laser beam application means 52 for applying a laser beam along the street 23, thereby performing the alignment of a laser beam application position. The alignment of the laser beam application position is also carried out similarly on streets that are formed on the semiconductor wafer 2 and extend in a direction perpendicular to the above predetermined direction.

After the street 23 formed on the semiconductor wafer 2 held on the chuck table 51 is detected and the alignment of the laser beam application position is carried out as described above, the chuck table 51 is moved to a laser beam application area where the condenser 524 of the laser beam application means 52 for applying a laser beam is located as shown in FIG. 6(a), to bring one end (left end in FIG. 6(a)) of the predetermined street 23 to a position right below the condenser 524 of the laser beam application means 52. The chuck table 51, that is, the semiconductor wafer 2 is moved in the direction indicated by the arrow X1 in FIG. 6(a) at a predetermined processing-feed rate while a first pulse laser beam 525 is applied from the condenser 524. When the application position of the laser beam application means 52 reaches the other end (right end in FIG. 6(b)) of the street 23 as shown in FIG. 6(b), the application of the first pulse laser beam 525 is suspended and the movement of the chuck table 51, that is, the semiconductor wafer 2 is stopped.

Thereafter, the chuck table 51, that is, the semiconductor wafer 2 is moved about 40 μm to a direction (indexing-feed direction) perpendicular to the sheet. This indexing-feed amount is set to a value larger than the width of the cutting blade which will be described later but not larger than the width of the street 23. The chuck table 51, that is, the semiconductor wafer 2 is moved in the direction indicated by the arrow X2 in FIG. 6(b) at a predetermined processing-feed rate while the first pulse laser beam 525 is applied from the laser beam application means 52. When the application position of the laser beam application means 52 reaches the position shown in FIG. 6(a), the application of the first pulse laser beam 525 is suspended and the movement of the chuck table 51, that is, the semiconductor wafer 2 is stopped.

While the chuck table 51, that is, the semiconductor wafer 2 is reciprocated as described above, the first pulse laser beam 525 is applied to the street 23 with its focusing point P on the top surface of the street 23 at a distance wider than the width of the cutting blade later described, as shown in FIG. 7.

The first groove forming step is carried out under the following processing conditions, for example.

Light source of laser beam: YVO4 laser or YAG laser
Wavelength: 355 nm
Repetition frequency: 100 kHz
Output: 0.5 W
Focusing spot diameter: 9.2 μm
Processing-feed rate: 600 mm/sec

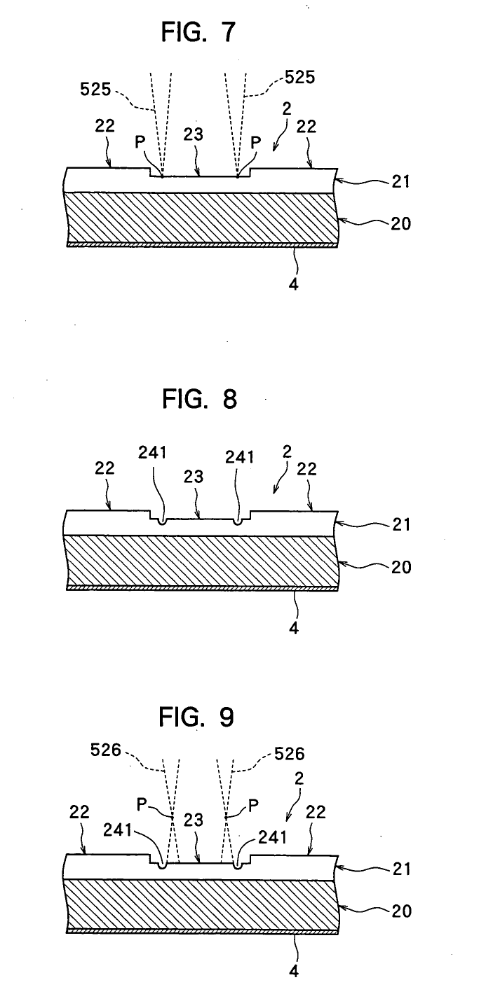

A pair of first laser grooves 241 and 241 are formed in the laminate 21 forming the street 23 of the semiconductor wafer 2 along the street 23 at a distance wider than the width of the cutting blade later described as shown in FIG. 8 by carrying out the above first groove forming step. Since the output of the first pulse laser beam 525 for forming the first laser grooves 241 and 241 is set to be lower than the output of a second pulse laser beam to be applied in the second groove forming step which will be described later, the films forming the laminate 21 are not peeled off. The depth of the first laser grooves 241 and 241 formed in the laminate 21 forming the street 23 of the semiconductor wafer 2 is desirably the depth of a film layer that is easily peeled off by the second laser beam to be applied in the second groove forming step. The first groove forming step is carried out on all the streets 23 formed on the semiconductor wafer 2.

After the first groove forming step is carried out on all the streets 23 formed on the semiconductor wafer 2, the second groove forming step for forming second laser grooves which reach the semiconductor substrate 20 in the street 23 between the outer sides of the first laser grooves 241 and 241 by applying a second laser beam to the laminate 21 of a region wider than the width of the cutting blade later described is carried out. This second groove forming step is carried out by using a laser beam machine similar to the laser beam machine shown in FIGS. 2 to 4.

That is, as shown in FIG. 9, the second pulse laser beam 526 is applied to the laminate 21 of a region wider than the width of the cutting blade later described, between the outer sides of the first laser grooves 241 and 241 in the street 23 of the semiconductor wafer 2. At this point, the focusing point P of the pulse laser beam 526 is preferably set to position about 0.2 mm above the top surface of the street 23 to widen the application ranges of the laser beam. The focusing point P of the pulse laser beam 526 may be set to position about 0.2 mm below the top surface of the street 23 to widen the application ranges of the laser beam.

The above second groove forming step is carried out under the following processing conditions, for example.

Light source of laser beam: YVO4 laser or YAG laser
Wavelength: 355 nm
Repetition frequency: 100 kHz
Output: 1.0 W
Focusing spot diameter: 9.2 μm
Processing-feed rate: 100 mm/sec

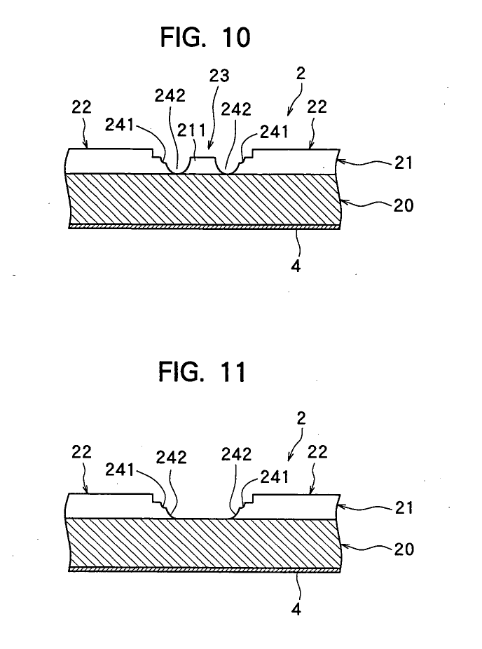

The output of the second pulse laser beam 526 applied in the above second groove forming step is set to be higher than the output of the first pulse laser beam 525 applied in the above first groove forming step. The second laser grooves 242 and 242 which reach the semiconductor substrate 20 are formed along the street 23 in the laminate 21 forming the street 23 of the semiconductor wafer 2 by carrying out the above second groove forming step, as shown in FIG. 10. Since the first laser grooves 241 and 241 are formed to the depth of an easily peelable layer in the laminate 21 forming the street 23 before the second laser grooves 242 and 242 are formed, even when the laminate 21 is removed by applying the second laser beam, as the semiconductor chips are divided off by the first laser grooves 241 and 241 at both sides, they are not affected by the peeling. As the second laser grooves 242 and 242 formed in the laminate 21 forming the street 23 of the semiconductor wafer 2 reach the semiconductor substrate 20, the laminate 21 forming the street 23 is completely separated from the semiconductor chips 22. In this embodiment, part 211 of the laminate 21 remains in the center of the street 23.

In the embodiment shown in FIG. 9 and FIG. 10, part 211 of the laminate 21 remains in the center of the street 23 of the semiconductor wafer 2 after the second groove forming step. This remaining part 211 of the laminate 21, however, can be removed by applying the above second pulse laser beam 526 to the remaining part 21 of the laminate 21 as shown in FIG. 11.

The first groove forming step and the second groove forming step for the semiconductor wafer 2 in which an insulating film laminated on the front surface 20a of the semiconductor substrate 20 is a low-dielectric film (Low-k film) formed of a film of an organic material, have been described above. A description is subsequently given of the first groove forming step and the second groove forming step for a semiconductor wafer 2 in which an insulating film laminated on the front surface 20a of the semiconductor substrate 20 is formed of silicon dioxide (SiO₂).

The above first groove forming step for the semiconductor wafer 2 in which an insulating film laminated on the front surface 20a of the semiconductor substrate 20 is formed of silicon dioxide (SiO₂) is carried out under the following processing conditions.

Light source of laser beam: YVO4 laser or YAG laser
Wavelength: 355 nm
Repetition frequency: 50 kHz
Output: 0.4 W
Focusing spot diameter: 9.2 μm
Processing-feed rate: 1 mm/sec

As shown in FIG. 8, first laser grooves 241 and 241 can be formed by carrying out the first groove forming step under the above processing conditions.

The above second groove forming step for the semiconductor wafer 2 in which an insulating film laminated on the front surface 20a of the semiconductor substrate 20 is formed of silicon dioxide (SiO₂) is carried out under the following processing conditions.

Light source of laser beam: YVO4 laser or YAG laser
Wavelength: 355 nm
Repetition frequency: 50 kHz
Output: 1.5 W
Focusing spot diameter: 9.2 μm
Processing-feed rate: 100 mm/sec

As shown in FIG. 10 and FIG. 11, second laser grooves 242 and 242 can be formed by carrying out the second groove forming step under the above processing conditions.

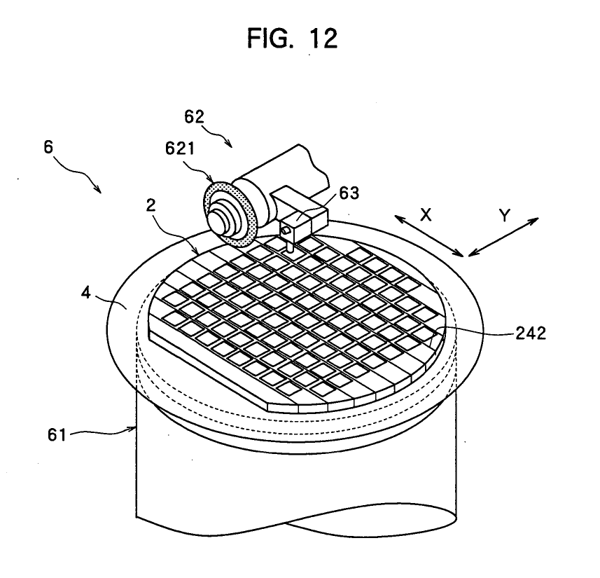

After the above first groove forming step and the second groove forming step are carried out on all the streets 23 formed on the semiconductor wafer 2, the cutting step for cutting the semiconductor wafer 2 along the streets 23 is carried out. In this cutting step, a cutting machine 6 which is generally used as a dicing machine as shown in FIG. 12 maybe used. That is, the cutting machine 6 comprises a chuck table 61 having a suction-holding means, a cutting means 62 having a cutting blade 621, and an image pick-up means 63 for picking up an image of the workpiece held on the chuck table 61.

The cutting step to be carried out with the above cutting machine 7 will be described with reference to FIGS. 12 to 14.

That is, as shown in FIG. 12, the semiconductor wafer 2 which has been subjected to the above first groove forming step and the second groove forming step is placed on the chuck table 61 of the cutting machine 6 in such a manner that the front surface 2a of the semiconductor wafer 2 faces up and held on the chuck table 61 by a suction means that is not shown. The chuck table 61 suction-holding the semiconductor wafer 2 is positioned right below the image pick-up means 63 by a moving mechanism that is not shown.

After the chuck table 61 is positioned right below the image pick-up means 63, alignment work for detecting the area to be cut of the semiconductor wafer 2 is carried out by the image pick-up means 53 and a control means that is not shown. That is, the image pick-up means 53 and the control means (not shown) carry out image processing such as pattern matching, etc. to align a street 23 formed in a predetermined direction of the semiconductor wafer 2 with the cutting blade 621 for cutting along the street 23, thereby performing the alignment of the area to be cut. The alignment of the area to be cut is also carried out on streets 23 that are formed on the semiconductor wafer 2 and extend in a direction perpendicular to the above predetermined direction.

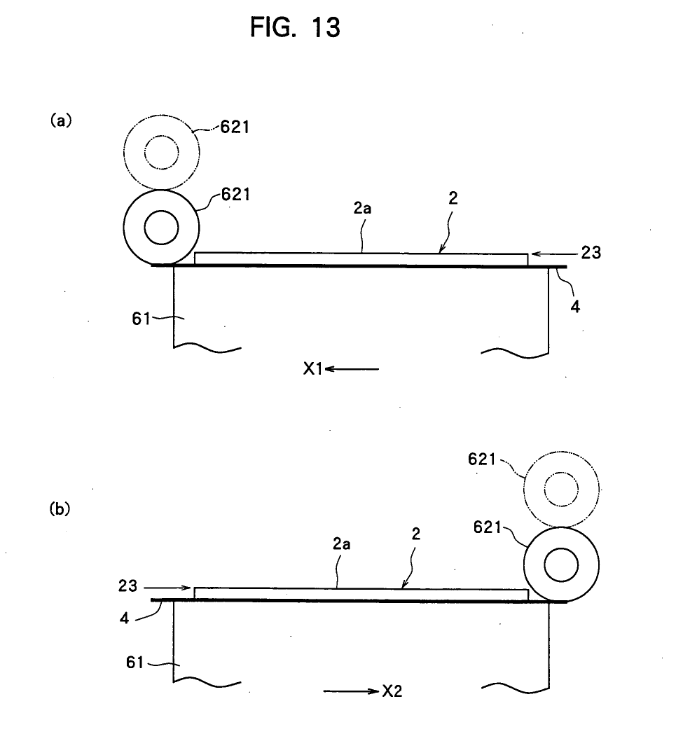

After the street 23 formed on the semiconductor wafer 2 held on the chuck table 61 is detected and the alignment of the area to be cut is carried out as described above, the chuck table 61 holding the semiconductor wafer 2 is moved to the cutting start position of the area to be cut. At this point, as shown in FIG. 13(a), the semiconductor wafer 2 is brought to a position where one end (left end in FIG. 13(a)) of the street 23 to be cut is located on the right side by a predetermined amount from a position right below the cutting blade 621. The semiconductor wafer 2 is also positioned such that the cutting blade 621 is located in the center between the second laser grooves 242 and 242 formed in the street 23.

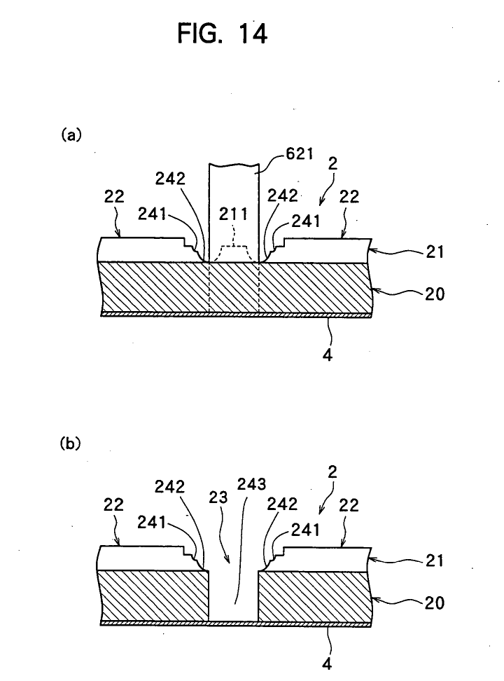

After the chuck table 61, that is, the semiconductor wafer 2 is thus brought to the cutting start position of the area to be cut, the cutting blade 621 is moved down from its standby position shown by a two-dot chain line in FIG. 13(a) to a predetermined cutting position shown by a solid line in FIG. 13(a). This cutting-feed position is set to a position where the lower end of the cutting blade 621 reaches the protective tape 4 affixed to the back surface of the semiconductor wafer 2, as shown in FIG. 14(a).

Thereafter, the cutting blade 621 is rotated at a predetermined revolution, and the chuck table 61, that is, the semiconductor wafer 2 is moved in the direction indicated by the arrow X1 in FIG. 13(a) at a predetermined cutting-feed rate. When the chuck table 61, that is, the semiconductor wafer 2 reaches a position where the other end (right end in FIG. 13(b)) of the street 23 is located on the left side by a predetermined amount from right below the cutting blade 621 as shown in FIG. 13(b), the movement of the chuck table 61, that is, the semiconductor wafer 2 is stopped. By thus moving the chuck table 61, that is, the semiconductor wafer 2, a cut groove 243 which reaches the back surface is formed between the second laser grooves 242 and 242 formed in the street 23 of the semiconductor wafer 2 as shown in FIG. 14(b), thereby dividing the wafer. When the area between the second laser grooves 242 and 242 is cut with the cutting blade 621 as described above, part 211 of the laminate 21 remaining between the second laser grooves 242 and 242 is cut with the cutting blade 621. Even when the part 211 is removed, the semiconductor chips 22 are divided off by the second laser grooves 242 and 242 at both sides, they are not affected by the peeling. When the remaining part 211 of the laminate 21 forming the street 23 is removed by the second groove forming step as shown in FIG. 11, only the semiconductor substrate 20 is cut with the cutting blade 621 in the cutting step.

The above cutting step is carried out under the following processing conditions, for example.
Cutting blade: outer diameter of 52 mm, thickness of 20 μm
Revolution of cutting blade: 30,000 rpm
Cutting-feed speed: 50 mm/sec

Thereafter, the cutting blade 621 is positioned to the standby position indicated by the two-dot chain line in FIG. 13(b), and the chuck table 61, that is, the semiconductor wafer 2 is moved in the direction indicated by the arrow X2 in FIG. 13(b) to return to the position shown in FIG. 13(a). The chuck table 61, that is, the semiconductor wafer 2 is indexing-fed by an amount corresponding to the interval between the streets 23 in a direction (indexing-feed direction) perpendicular to the sheet, to bring a street 23 to be cut next to a position corresponding to the cutting blade 621. After the street 23 to be cut next is located at a position corresponding to the cutting blade 621, the above-mentioned cutting step is carried out.

The above-mentioned cutting step is carried out on all the streets 23 formed on the semiconductor wafer 2. As a result, the semiconductor wafer 2 is cut along the second laser grooves 242 formed in the streets 23, and is divided into individual semiconductor chips 20.

1. A method of dividing a semiconductor wafer comprising semiconductor chips which are composed of a laminate consisting of an insulating film and a functional film formed on the front surface of a semiconductor substrate and which are sectioned by streets, into individual semiconductor chips by cutting the semiconductor wafer with a cutting blade along the streets, the method comprising:
a first groove forming step for forming a pair of first laser grooves in the laminate by applying a first laser beam to each of the streets at a distance wider than the width of the cutting blade;
a second groove forming step for forming second laser grooves which reach the semiconductor substrate between the both outer sides of the pair of first laser grooves in the street by applying a second laser beam to the laminate of a region wider than the width of the cutting blade; and
a cutting step for cutting the semiconductor substrate with the cutting blade along the second laser grooves.

2. The semiconductor wafer dividing method according to claim 1, wherein the output of the first laser beam is set to be lower than the output of the second laser beam.

3. The semiconductor wafer dividing method according to claim 1, wherein the depth of the first laser grooves is set to the depth of an easily peelable film layer when the second laser beam is applied in the second groove forming step.
